(19) United States
(12) Patent Application Publication
(10) Pub. No.: US 2026/0107665 A1
(43) Pub. Date: Apr. 16, 2026

(54) DISPLAY DEVICE AND ELECTRONIC DEVICE

(71) Applicant: Samsung Display Co., Ltd., Yongin-si (KR)

(72) Inventors: SUNKWANG KIM, Yongin-si (KR); KANGMOON JO, Yongin-si (KR); SI HYUN AHN, Yongin-si (KR); KYEUK LEE, Yongin-si (KR)

(21) Appl. No.: 19/235,351

(22) Filed: Jun. 11, 2025

(30) Foreign Application Priority Data
Oct. 11, 2024 (KR) 10-2024-0138840

(51) Int. Cl. H10K 59/80; H10K 59/131

(52) U.S. Cl. CPC H10K 59/873; H10K 59/131

(57) ABSTRACT

A display device and an electronic device including the display device are disclosed. The display device may include a base layer divided into a display area and a non-display area around the display area, a circuit layer arranged on the base layer and including at least one metal layer and an insulating (e.g., electrically insulating) layer on the at least one metal layer, and a display element layer arranged on the circuit layer and including a light emitting element electrically connected to the at least one metal layer. The at least one metal layer may include a first metal layer and a second metal layer which are arranged in the non-display area. The insulating layer may include a pattern portion that is defined between the first metal layer and the second metal layer and that overlaps an opening portion that extends in a second direction that crosses the first direction.

### CROSS-REFERENCE TO RELATED APPLICATION

The present application claims priority to and the benefit of Korean Patent Application No. 10-2024-0138840, filed on Oct. 11, 2024, in the Korean Intellectual Property Office, the entire content of which is incorporated herein by reference.

### BACKGROUND

### 1. Field

One or more embodiments of the present disclosure relate to a display device and an electronic device including the display device, and, for example, to a display device and electronic device including the display device with improved or enhanced reliability.

### 2. Description of the Related Art

Display devices, such as televisions, monitors, smartphones, and/or tablet computers, include display panels that provide images for users. One or more display panels, such as liquid crystal display panels, organic light emitting diode display panels, electro wetting display panels, and/or electrophoretic display panels, have been developed.

Thin-film encapsulation layers may include organic layers and inorganic layers. Liquid organic materials are cured to form the organic layers. Development is ongoing for structures that control the spreading of organic materials, ensuring that these materials are formed in desired or suitable regions.

Recent research focuses on reducing dead spaces in the display panels of display devices. Concurrently, development is required or desired for organic material spreading structures to prevent or reduce the flow of organic materials from the display panels (or to reduce a degree or occurrence of which the organic materials of the organic layers flow out of the display panels).

### SUMMARY

One or more aspects of embodiments of the present disclosure are directed toward a display device capable of effectively or suitably blocking flow (or reducing a degree or occurrence of flow) of an organic layer which constitutes an encapsulation layer.

Additional aspects of embodiments will be set forth in part in the description which follows and, in part, will be apparent from the description or may be learned by practice of the presented embodiments of the disclosure.

In one or more embodiments, a display device includes a base layer which is divided into a display area and a non-display area arranged around the display area, a circuit layer which is arranged on the base layer and includes at least one metal layer and an insulating (e.g., electrically insulating) layer arranged on the at least one metal layer, and a display element layer which is arranged on the circuit layer and includes a light emitting element electrically connected to the at least one metal layer. The at least one metal layer includes a first metal layer and a second metal layer which are arranged in the non-display area and spaced and/or apart (e.g., spaced apart or separated) from each other in a first direction. The insulating layer includes a pattern portion that is defined between the first metal layer and the second metal layer and that overlaps an opening portion that extends in a second direction that crosses the first direction.

The display device may further include a dam that is arranged in the non-display area and that extends in the first direction, wherein the pattern portion is adjacent to the dam.

The dam may include a recessed portion defined in an area that overlaps the opening portion.

The dam may include substantially the same material as the pattern portion.

The dam may include a plurality of dams, and the plurality of dams may be spaced from each other in the second direction.

The display device may further include an encapsulation layer arranged on the display element layer and including a first inorganic layer, an organic layer on the first inorganic layer, and a second inorganic layer on the organic layer.

The display device may further include a dam that is arranged in the non-display area and that extends in the first direction, wherein the organic layer is in contact with the dam.

The insulating layer may include an open portion which exposes at least a portion of the first metal layer and the second metal layer, wherein the pattern portion is in the open portion.

The pattern portion may include a surface concave in the first direction or in an opposite direction to the first direction.

The pattern portion may include a zigzag shape (e.g., a substantially zigzag shape).

The pattern portion may include a first portion that extends in the first direction and a second portion that extends in the second direction.

The first metal layer may be to receive a first voltage, and the second metal layer may be to receive a second voltage having a higher level than the first voltage.

The first metal layer may be electrically connected to a cathode of the light emitting element through a contact hole defined in the insulating layer.

A distance by which the first metal layer and the second metal layer are spaced from each other may be about 80 μm to about 120 μm.

The at least one metal layer may further include a third metal layer spaced from the second metal layer in the first direction, wherein a sub-opening portion is defined between the second metal layer and the third metal layer.

The insulating layer may further include an auxiliary pattern portion that overlaps the sub-opening portion.

The auxiliary pattern portion may include substantially the same shape as the pattern portion.

The auxiliary pattern portion may include a plurality of auxiliary pattern portions, and the plurality of auxiliary pattern portions may be substantially the same in shape.

The third metal layer may be to receive a data voltage.

In one or more embodiments, an electronic device includes a housing, an electronic module arranged inside the housing, and a display device that overlaps the electronic module. The display device includes a base layer which is divided into a display area and a non-display area arranged around the display area, a circuit layer which is arranged on the base layer and includes at least one metal layer and an insulating (e.g., electrically insulating) layer arranged on the at least one metal layer, and a display element layer which is arranged on the circuit layer and includes a light emitting element electrically connected to the at least one metal layer. The at least one metal layer includes a first metal layer and a second metal layer which are arranged in the non-display area and spaced and/or apart (e.g., spaced apart or separated) from each other in a first direction. The insulating layer includes a pattern portion that is defined between the first metal layer and the second metal layer and that overlaps an opening portion that extends in a second direction that crosses the first direction.

### BRIEF DESCRIPTION OF THE DRAWINGS

The accompanying drawings are included to provide a further understanding of embodiments of the subject matter of the present disclosure and are incorporated in and constitute a part of this specification. The drawings illustrate embodiments of the subject matter of the present disclosure and, together with the description, serve to explain principles of embodiments of the subject matter of the present disclosure. In the drawings:

FIG. 1 is a perspective view of an electronic device according to one or more embodiments of the present disclosure;

FIG. 2A is an exploded perspective view of an electronic device according to one or more embodiments of the present disclosure;

FIG. 2B is a cross-sectional view of a display module according to one or more embodiments of the present disclosure;

FIG. 3 is a plan view of a display panel according to one or more embodiments of the present disclosure;

FIG. 4A is a cross-sectional view of a display panel that corresponds to the line I-I′ in FIG. 3 according to one or more embodiments of the present disclosure;

FIG. 4B is a cross-sectional view of a display panel that corresponds to the line II-II′ in FIG. 3 according to one or more embodiments of the present disclosure;

FIG. 5 is an enlarged view of area AA′ as illustrated in FIG. 3;

FIG. 6 is a cross-sectional view of a display panel that corresponds to the line III-III′ in FIG. 5 according to one or more embodiments of the present disclosure;

FIG. 7A is a cross-sectional view of a display panel that corresponds to the line IV-IV′ in FIG. 5 according to one or more embodiments of the present disclosure;

FIG. 7B is a cross-sectional view of a display panel that corresponds to the line V-V′ in FIG. 5 according to one or more embodiments of the present disclosure;

FIGS. 8A and 8B are each an enlarged view of a portion of a display panel according to one or more embodiments of the present disclosure; and

FIG. 9 is an enlarged view of area BB′ as illustrated in FIG. 3.

### DETAILED DESCRIPTION

The subject matter of the present disclosure will be described more fully hereinafter with reference to the accompanying drawings, in which embodiments of the present disclosure are shown. The subject matter of the present disclosure may, however, be embodied in different forms and should not be construed as being limited to one or more embodiments set forth herein. Rather, these embodiments are provided as examples so that this disclosure will be thorough and complete, and will fully convey the aspects and features of the present disclosure to those skilled in the art.

In the present disclosure, it will be understood that if (e.g., when) an element (or a region, a layer, a portion, and/or the like) is referred to as being “on”, “connected to”, or “coupled to” another element, it may be directly on, directly connected to, or directly coupled to the other element, or other elements may be arranged therebetween. In contrast, if (e.g., when) an element is referred to as being “directly on”, “directly connected to”, or “directly coupled to” another element, there may be no intervening elements present therebetween.

Like reference numerals or symbols refer to like elements throughout, and duplicative descriptions thereof may not be provided. In the drawings, the thickness, ratio, and size of the elements may be exaggerated to effectively or suitably illustrate the technical contents.

As used herein, the term “and/or” includes any and all combinations of one or more of the associated listed elements.

In the context of the present disclosure and unless otherwise defined, the terms “use,” “using,” and “used” may be considered synonymous with the terms “utilize,”“utilizing,”and “utilized,”respectively.

As utilized herein, the terms “substantially,” “about,” or similar terms are used as terms of approximation and not as terms of degree and are intended to account for the inherent deviations in measured or calculated values that would be recognized by those of ordinary skill in the art. “About” as used herein is inclusive of the stated value and refers to being within an acceptable range of deviation for the particular value as determined by one of ordinary skill in the art, considering the measurement in question and the error associated with measurement of the particular quantity (e.g., the limitations of the measurement system). For example, “about” may refer to being within one or more standard deviations, or within ±30%, ±20%, ±10%, or ±5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

It will be understood that, although the terms “first”, “second”, and/or the like may be used herein to describe one or more suitable elements, the elements are not to be limited by these terms. These terms are only used to distinguish one element, component, region, layer, or section from another element, component, region, layer, or section. For instance, a first element, a first component, a first region, a first layer, or a first section discussed herein may be termed a second element, a second component, a second region, a second layer, or a second section without departing from the scope of the present disclosure. Similarly, a second element, a second component, a second region, a second layer, or a second section may be termed a first element, a first component, a first region, a first layer, or a first section.

In the present disclosure, the singular expressions “a”, “an”, and “the” are intended to include the plural forms as well, unless the context clearly indicates otherwise.

The terms “below”, “under”, “on the lower side”, “above”, “over”, “on the upper side”, and/or the like may be used to describe the relationships between the elements illustrated in the drawings. These terms are relative concepts and are described on the basis of the directions indicated in the drawings.

Unless otherwise defined, all terms (including technical and scientific terms) used herein have substantially the same meaning as commonly understood by one of ordinary skill in the art to which the present disclosure belongs. It will be further understood that terms, such as those defined in dictionaries that are generally available or generally used, should be interpreted as having a meaning that is consistent with their meaning in the context of the relevant art and will not be interpreted in an idealized or overly formal sense unless expressly so defined herein.

It should be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

The utilization of “may” when describing embodiments of the present disclosure refers to “one or more embodiments of the present disclosure.”

Hereinafter, one or more embodiments of the present disclosure will be described in more detail with reference to the accompanying drawings.

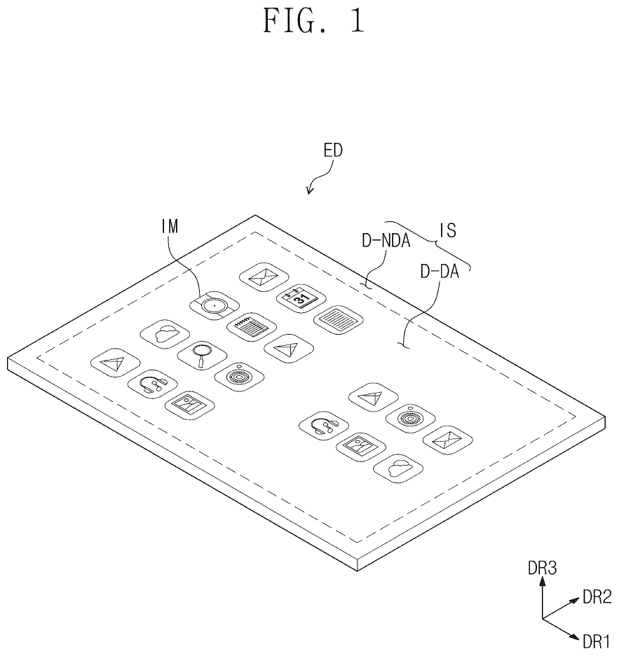

FIG. 1 is a perspective view of an electronic device according to one or more embodiments of the present disclosure.

Referring to FIG. 1, an electronic device ED may be a device that is to be activated in response to an electrical signal and display an image. The electronic device ED may include one or more suitable embodiments which provide an image IM for a user, and for example, the electronic device ED may include a large-sized device, such as a television and/or an outdoor billboard, and also a small and/or medium-sized device, such as a monitor, a mobile phone, a tablet computer, a navigation device, and/or a game console. However, one or more embodiments of the electronic device ED are examples, and are not limited to any one unless departing from the spirit and scope of the present disclosure.

The electronic device ED may have a rectangular shape (e.g., a substantially rectangular shape) having long sides that extend in a first direction DR1 and having short sides that extend in a second direction DR2 on a plane (e.g., in a plan view). However, the electronic device ED is not limited thereto and may have one or more suitable shapes, such as a circular shape (e.g., a substantially circular shape) and/or a polygonal shape (e.g., a substantially polygonal shape).

The electronic device ED may be to display the image IM in a third direction DR3 through a display surface IS parallel (e.g., substantially parallel) to a plane defined by the first direction DR1 and the second direction DR2. The third direction DR3 may be substantially parallel (e.g., substantially parallel) to a normal direction to the display surface IS. The display surface IS on which the image IM is displayed may correspond to a front surface of the electronic device ED. The image IM may include not only a dynamic image but also a still image. FIG. 1 illustrates icon images as an example of the image IM.

In one or more embodiments, a front surface (or top surface) and a rear surface (or bottom surface) of each of members, which constitute the electronic device ED, may be defined on the basis of the third direction DR3. The front surface and the rear surface may oppose each other in the third direction DR3, and a normal direction to each of the front surface and the rear surface may be parallel (e.g., substantially parallel) to the third direction DR3. A separation distance between the front surface and the rear surface, which is defined along the third direction DR3, may correspond to a thickness of the member.

The term “on a plane” or “in a plan view” used herein may be defined as being in a state if (e.g., when) viewed in the third direction DR3. The term “on a cross-section” or “in a cross-sectional view”) used herein may be defined as being in a state if (e.g., when) viewed in the first direction DR1 or the second direction DR2. However, directions indicated by the first direction DR1, the second direction DR2, and the third direction DR3 are relative concepts and may be changed to other directions.

As an example, FIG. 1 illustrates the electronic device ED having a flat (e.g., substantially flat) display surface IS. However, the shape of the display surface IS of the electronic device ED is not limited thereto and may be a curved shape or a three-dimensional shape.

The electronic device ED may be flexible. The term “flexible” indicates a characteristic of being capable of bending and may include all from a fully folded structure to a structure capable of bending at the level of several nanometers. For example, the flexible electronic device ED may include a curved device and/or a foldable device. However, the electronic device ED is not limited thereto and may be rigid.

The display surface IS of the electronic device ED may include a display part D-DA and a non-display part D-NDA. The display part D-DA may be a portion on which the image IM is displayed within the front surface of the electronic device ED, and the image IM may be visible to a user through the display part D-DA. In one or more embodiments, the display part D-DA having a rectangular shape (e.g., a substantially rectangular shape) on a plane (e.g., in a plan view) is illustrated as an example, but the display part D-DA may have one or more suitable shapes according to the design of the electronic device ED.

The non-display part D-NDA may be a portion on which the image IM is not displayed within the front surface of the electronic device ED. The non-display part D-NDA may be a portion which has a certain (e.g., set or predetermined) color and blocks light (or reduces a degree or occurrence of light). The non-display part D-NDA may be adjacent to the display part D-DA. For example, the non-display part D-NDA may be arranged outside the display part D-DA to be around (e.g., surround) the display part D-DA. However, this is illustrated as an example, and the non-display part D-NDA may be adjacent to only one side of the display part D-DA or arranged not on the front surface but on a side surface of the electronic device ED. The non-display part D-NDA is not limited thereto and may not be provided.

The electronic device ED according to one or more embodiments may be to detect an external input applied from the outside. The external input may include one or more suitable types (kinds), such as pressure, temperature, and/or light provided from the outside. The external input may include not only an input caused by touching the electronic device ED (e.g., touch by the user's hand or pen) but also an input (e.g., hovering) applied by approaching the electronic device ED.

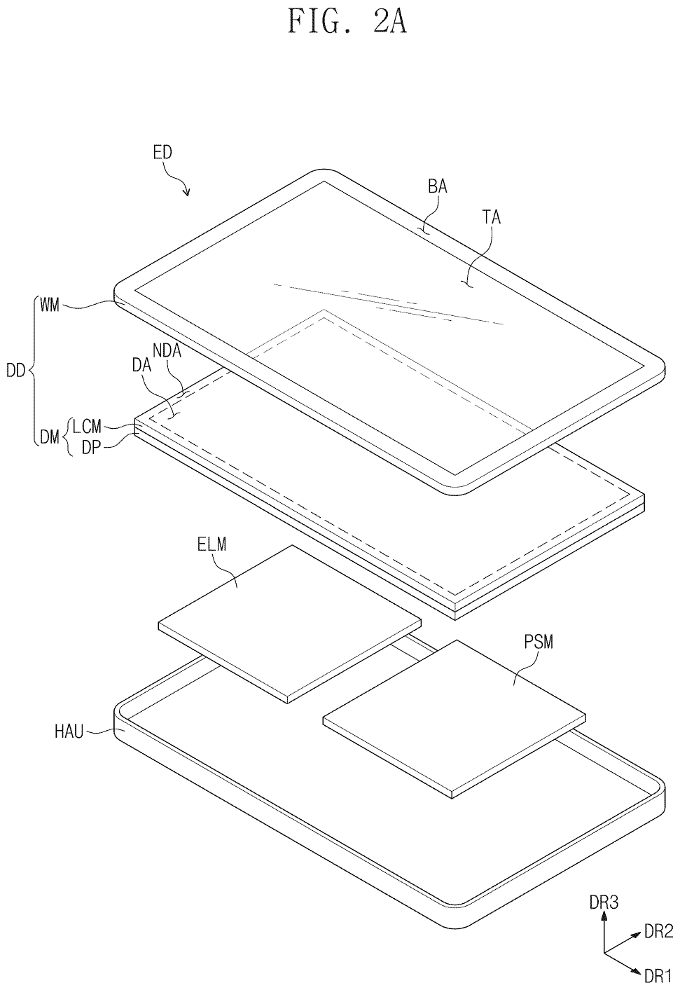

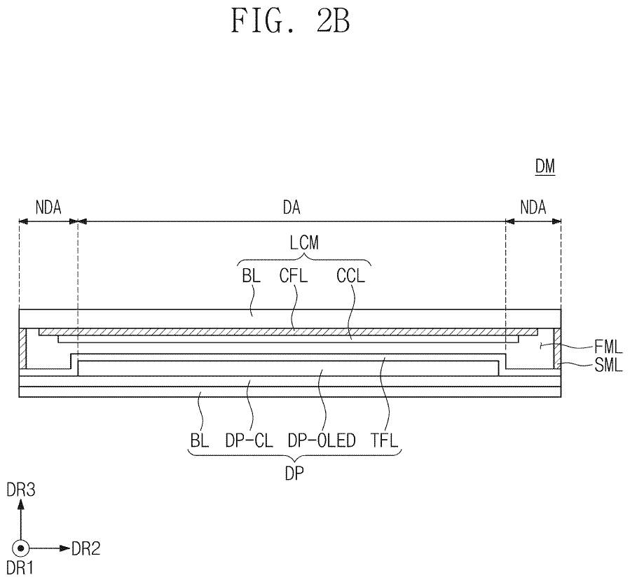

FIG. 2A is an exploded perspective view of an electronic device according to one or more embodiments of the present disclosure. FIG. 2B is a cross-sectional view of a display module according to one or more embodiments of the present disclosure.

Referring to FIGS. 2A and 2B, an electronic device ED may include a display device DD, an electronic module ELM, a power module PSM, and a housing HAU. The display device DD may include a window WM and a display module DM. The display module DM may include a display panel DP and a light control member LCM arranged on the display panel DP.

The window WM and the housing HAU may be coupled to constitute an outer appearance of the electronic device ED and may provide an inner space capable of accommodating components, such as the display module DM, of the electronic device ED.

The window WM may be arranged on the display module DM. The window WM may be to protect the display module DM from an external impact. A front surface of the window WM may correspond to the display surface IS of the electronic device ED as described in one or more embodiments. The front surface of the window WM may include a transmission area TA and a bezel area BA.

The transmission area TA of the window WM may be an optically transparent (e.g., substantially transparent) area. The window WM may be to transmit the image IM provided by the display module DM through the transmission area TA, and this image IM may be visible to a user. The transmission area TA may correspond to the display part D-DA of the electronic device ED as described in one or more embodiments.

The window WM may include an optically transparent (e.g., substantially transparent) insulating (e.g., electrically insulating) material. For example, the window WM may include glass, sapphire, plastic, and/or the like. The window WM may have a single-layer structure or a multilayer structure. The window WM may further include functional layers, such as an anti-fingerprint layer, a phase control layer, and/or a hard coating layer, which are arranged on an optically transparent (e.g., substantially transparent) substrate.

The bezel area BA of the window WM may be an area provided by depositing, coating, and/or printing a material having a certain (e.g., set or predetermined) color on a transparent (e.g., substantially transparent) substrate. The bezel area BA of the window WM may prevent one component of the display module DM, that overlaps the bezel area BA, from being visible from the outside (or reduce a degree to or occurrence of which one component of the display module DM, that overlaps the bezel area BA, is visible from the outside). The bezel area BA may correspond to the non-display part D-NDA of the electronic device ED as described in one or more embodiments.

The display module DM may be arranged below the window WM. The display module DM may be to display an image in response to an electrical signal. The display module DM may include a display area DA and a non-display area NDA adjacent to the display area DA.

The display area DA may be an area that is to be activated in response to an electrical signal and outputs an image. The display area DA of the display module DM may overlap the transmission area TA of the window WM. In the present disclosure, if (e.g., when) “an area/portion and an area/portion overlap each other”, it is not limited to the meaning that the areas/portions have substantially the same surface area and/or substantially the same shape. The image output from the display area DA may be visible from the outside through the transmission area TA.

The non-display area NDA may be adjacent to the display area DA. For example, the non-display area NDA may be around (e.g., surround) the display area DA. However, the non-display area NDA is not limited thereto and may be defined to have one or more suitable shapes. The non-display area NDA may be an area in which a driving circuit or driving line to drive elements arranged in the display area DA, one or more suitable signal lines which provide electrical signals, and pads are arranged. The non-display area NDA of the display module DM may overlap the bezel area BA of the window WM, and due to the bezel area BA, components arranged in the non-display area NDA may be prevented from being visible from the outside (or a degree to or occurrence of which components arranged in the non-display area NDA are visible from the outside may be reduced).

The display panel DP according to one or more embodiments may be an emissive display panel, but embodiments of the present disclosure are not limited thereto. For example, the display panel DP may be an organic light emitting display panel, an inorganic light emitting display panel, or a quantum dot light emitting display panel. An emission layer of the organic light emitting display panel may include an organic light emitting material, and an emission layer of the inorganic light emitting display panel may include an inorganic light emitting material. An emission layer of the quantum dot light emitting display panel may include a quantum dot, a quantum rod, and/or the like. Hereinafter, the display panel DP may be described as the organic light emitting display panel.

The display panel DP may include a base layer BL, a circuit layer DP-CL, a display element layer DP-OLED, and an encapsulation layer TFL.

The base layer BL may provide a base surface on which the circuit layer DP-CL is arranged. The base layer BL may be a rigid substrate, but the base layer BL is not limited thereto and may be a flexible substrate.

The circuit layer DP-CL may be arranged on the base layer BL. The circuit layer DP-CL may include driving elements, such as transistors, signal lines, and signal pads. The display element layer DP-OLED may include light emitting elements that overlap the display area DA. The light emitting elements of the display element layer DP-OLED may be electrically connected to the driving elements of the circuit layer DP-CL and output light through the display area DA in response to signals of the driving elements.

The encapsulation layer TFL may be arranged on the display element layer DP-OLED and seal the light emitting elements. The encapsulation layer TFL may include a plurality of thin films. The thin films of the encapsulation layer TFL may be arranged to improve or enhance optical efficiency of the light emitting elements or protect the light emitting elements.

The light control member LCM may be arranged on the display panel DP. The light control member LCM may be provided on the display panel DP and then coupled to the display panel DP through a bonding process using a sealing member SML.

However, embodiments of the present disclosure are not limited thereto, and the light control member LCM may be directly arranged on the display panel DP. In the present disclosure, if (e.g., when) a component is formed through a substantially continuous process with no separate adhesive layer and/or adhesive member arranged, it may be expressed as “being directly arranged”. For example, the expression “the light control member LCM is directly arranged on the display panel DP” may indicate that the display panel DP is formed, and then a component of the light control member LCM is formed on a base surface, provided by the display panel DP, through a substantially continuous process.

The light control member LCM may be to convert a wavelength of light provided by the display panel DP, e.g., source light, or selectively transmit the source light. For example, the light control member LCM may include light control patterns which may be to convert optical properties of the source light provided by the display panel DP. The light control member LCM may be to control color purity and/or color gamut ratios of light emitted from the electronic device ED and may prevent reflection of external light incident from the outside of the electronic device ED (or reduce a degree or occurrence of reflection of external light incident from the outside of the electronic device ED).

The light control member LCM may include a base layer BL, a color filter layer CFL, and a light control layer CCL. The base layer BL may be arranged to be opposite to (e.g., face) the base layer BL of the display panel DP, the color filter layer CFL may be arranged on the base layer BL, and the light control layer CCL may be arranged between the display panel DP and the base layer BL.

The light control layer CCL may include a quantum dot which is to convert the wavelength of the source light provided by the display panel DP, or further include a transmission part which is to transmit the source light. The source light having passed through the quantum dot included in the light control layer CCL may be output as light of a different color from a color of the source light.

The color filter layer CFL may include color filters, and the color filters may be to transmit or absorb light having passed through the light control layer CCL according to colors. The color filter layer CFL may be to absorb light, which is not converted by the light control layer CCL, to prevent the color purity of the electronic device ED from being decreased (or to reduce a degree to or occurrence of which the color purity of the electronic device ED decreases). In one or more embodiments, the color filter layer CFL may be to filter the external light to have substantially the same colors as pixels to prevent the reflection of the external light (or to reduce a degree or occurrence of the reflection of the external light).

The sealing member SML may be arranged in the non-display area NDA, which is an edge portion of the display module DM, and prevent foreign matter, oxygen, moisture, and/or the like from being introduced into the display module DM from the outside of the display module DM (or reduce a degree to or occurrence of which foreign matter, oxygen, moisture, and/or the like are introduced into the display module DM from the outside of the display module DM). The sealing member SML may include a sealant including a curable resin.

The display module DM according to one or more embodiments may further include a filling layer FML arranged between the display panel DP and the light control member LCM. The filling layer FML may fill a space between the display panel DP and the light control member LCM. The filling layer FML may be to function as a buffer between the display panel DP and the light control member LCM. In one or more embodiments, the filling layer FML may be to absorb impact and increase or enhance the strength of the display module DM.

The filling layer FML may include a filling resin including a polymer resin. For example, the filling layer FML may include an acryl-based resin, an epoxy-based resin, and/or the like. However, the light control member LCM according to one or more embodiments may be directly arranged on the display panel DP, and accordingly, the filling layer FML and the sealing member SML may not be provided. In one or more embodiments in which the light control member LCM is directly arranged on the display panel DP, the base layer BL of the light control member LCM may not be provided.

The electronic module ELM and the power module PSM may be arranged below the display module DM. The electronic module ELM and the power module PSM may be electrically connected to each other through a separate circuit board.

The power module PSM may be to supply power that is desired or required for an operation of the electronic device ED. For example, the power module PSM may include a general battery module.

The electronic module ELM may include one or more suitable functional modules that are to operate the electronic device ED. For example, the electronic module ELM may include a control module, a wireless communication module, an image input module, a sound input module, a sound output module, a memory, an optical module, an external interface module, and/or the like. The electronic module ELM may include a main circuit board, and the modules of the electronic module ELM may be mounted on the main circuit board or electrically connected to the main circuit board through a separate circuit board.

The control module of the electronic module ELM may be to control an overall operation of the electronic device ED. For example, the control module may be to activate or inactivate the display module DM in accordance with a user's input. The control module may include at least one microprocessor. The optical module of the electronic module ELM may include a camera module, a proximity sensor, a biometric sensor to recognize a user's body part (e.g., fingerprint, iris, and/or face), a lamp to output light, and/or the like.

The housing HAU may be arranged below the display module DM and accommodate the display module DM, the electronic module ELM, and the power module PSM. The housing HAU may be to absorb an impact applied to the display module DM from the outside and prevent foreign matter, moisture, and/or the like from being penetrated into the display module DM (or reduce a degree to or occurrence of which foreign matter, moisture, and/or the like penetrate into the display module DM), thereby protecting the display module DM. The housing HAU according to one or more embodiments may be provided in a shape in which a plurality of accommodation members are coupled to each other.

The electronic device ED may further include an input sensing module. The input sensing module may be to obtain coordinate information of an external input applied from the outside of the electronic device ED. The input sensing module may be driven by one or more suitable methods, such as a capacitance method, a resistive method, an infrared method, a sonic method, and/or a pressure method, and embodiments of the present disclosure are not limited to thereto.

In one or more embodiments, the input sensing module may be arranged on the display module DM. The input sensing module may be directly arranged on the display module DM through a substantially continuous process, but the input sensing module is not limited thereto and may be manufactured separately from the display module DM and attached onto the display module DM through an adhesive layer. However, embodiments of the present disclosure are not limited thereto, and the input sensing module may be arranged between components of the display module DM. For example, the input sensing module may be arranged between the display panel DP and the light control member LCM.

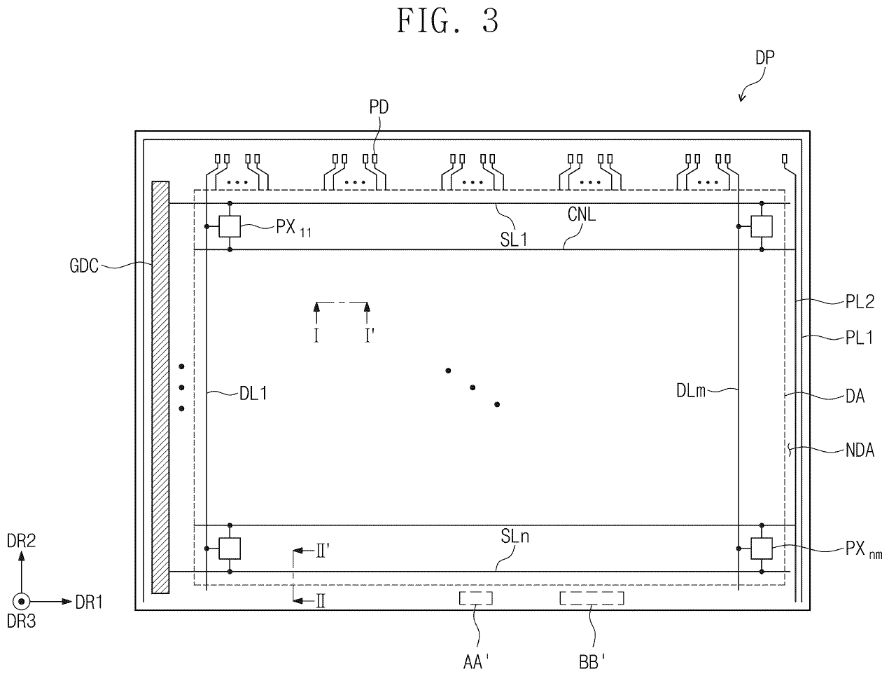

FIG. 3 is a plan view of a display panel according to one or more embodiments of the present disclosure.

Referring to FIG. 3, a display panel DP may include pixels PX₁₁ to PXₙₘ arranged in a display area DA, signal lines SL1 to SLn and DL1 to DLm electrically connected to the PX₁₁ to PXₙₘ, and power lines PL1 and PL2. Herein, m and n may each be a natural number. The display panel DP may further include a driving circuit GDC and pads PD, which are arranged in a non-display area NDA.

Each of the pixels PX₁₁ to PXₙₘ may include a light emitting element, and a pixel driving circuit including a plurality of transistors (e.g., a switching transistor, a driving transistor, and/or the like) connected to the light emitting element, and a capacitor. The pixels PX₁₁ to PXₙₘ may be to emit light in response to electrical signals applied to the pixels PX₁₁ to PXₙₘ. As an example, FIG. 3 illustrates the pixels PX₁₁ to PXₙₘ arranged in the form of a matrix, but an arrangement shape of the pixels PX₁₁ to PXₙₘ is not limited thereto.

The signal lines SL1 to SLn and DL1 to DLm may include scan lines SL1 to SLn and data lines DL1 to DLm. Each of the pixels PX₁₁ to PXₙₘ may be connected to a corresponding scan line among the scan lines SL1 to SLn, and a corresponding data line among the data lines DL1 to DLm. Each of the pixels PX₁₁ to PXₙₘ may be to receive data voltages from the corresponding data line among the data lines DL1 to DLm. According to the configuration or arrangement of the pixel driving circuit of the pixels PX₁₁ to PXₙₘ, more types (kinds) of signal lines may be provided in the display panel DP.

The driving circuit GDC may include a gate driving circuit. The gate driving circuit may be to generate gate signals and sequentially output the gate signals to the scan lines SL1 to SLn. The gate driving circuit may further be to output another control signal to the pixel driving circuit of the pixels PX₁₁ to PXₙₘ.

The driving circuit GDC and the pixels PX₁₁ to PXₙₘ according to one or more embodiments may include a plurality of transistors formed through a low temperature polycrystalline silicon (LTPS) process, a low temperature polycrystalline oxide (LTPO) process, and/or an oxide semiconductor process.

The pads PD may be arranged on the non-display area NDA along one direction. The pads PD may be portions that are connected to a circuit board. Each of the pads PD may be connected to corresponding signal lines among the signal lines SL1 to SLn and DL1 to DLm and connected to corresponding pixels among the pixels PX₁₁ to PXₙₘ through the signal line. The pads PD may have a shape of one body together with the signal lines SL1 to SLn and DL1 to DLm. However, the pads PD are not limited thereto and may be arranged on a different layer from the signal lines SL1 to SLn and DL1 to DLm to be connected to the signal lines SL1 to SLn and DL1 to DLm through a contact hole.

The power lines PL1 and PL2 may include a first power line PL1 and a second power line PL2. The first power line PL1 may be arranged in the non-display area NDA. The first power line PL1 may extend along an edge of the display panel DP. The first power line PL1 may be arranged outward from the driving circuit GDC.

The first power line PL1 may be to receive a first voltage. In one or more embodiments, the first power line PL1 may extend to the display area DA and be connected to corresponding pixels among the pixels PX₁₁ to PXₙₘ, and the first voltage may be provided to the corresponding pixels through the first power line PL1. The second power line PL2 may extend in the first direction DR1 and be arranged in the non-display area NDA. The second power line PL2 may be to receive a second voltage having a higher level than the first voltage. In one or more embodiments, the first power line PL1 and the second power line PL2 may be arranged at a lower end of the display panel DP. Each of the first power line PL1 and the second power line PL2 may be provided as a metal having a single-layer structure.

Connection lines CNL may extend in the first direction DR1 and be arranged in the second direction DR2. The connection lines CNL may be connected to the second power line PL2 and corresponding pixels among the pixels PX₁₁ to PXₙₘ. The second voltage may be applied to the corresponding pixels through the second power line PL2 and the connection lines CNL, which are connected to each other.

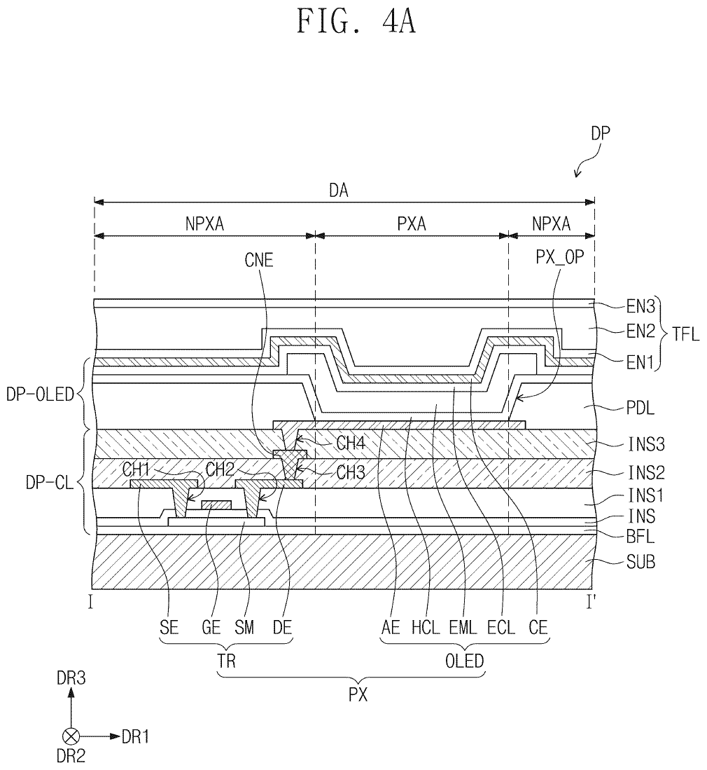

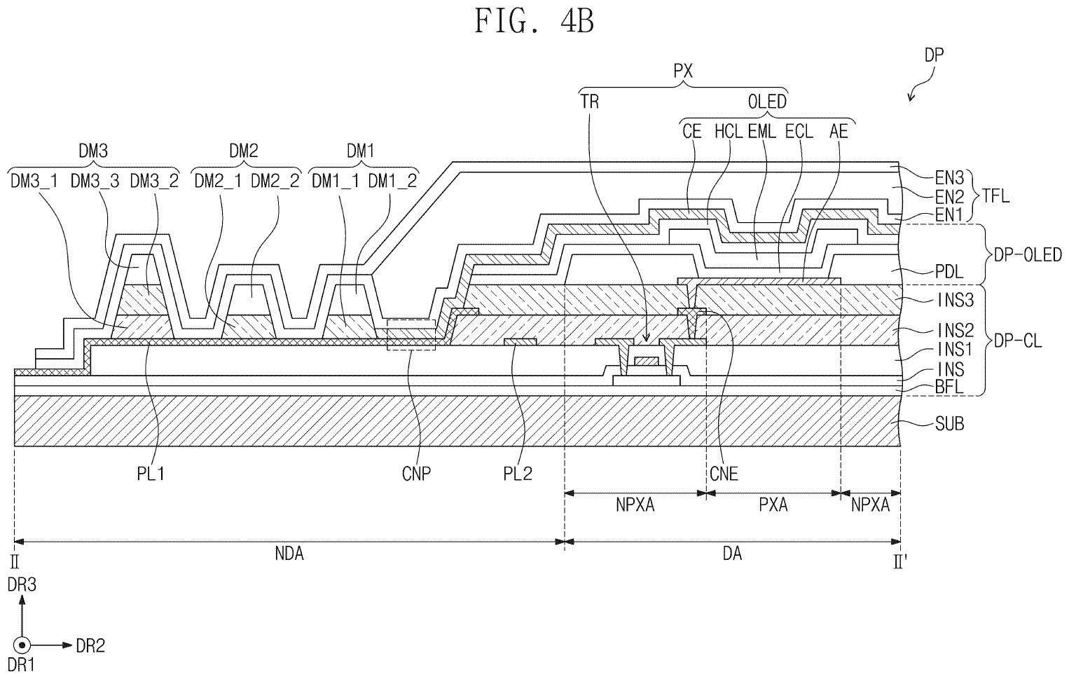

FIG. 4A is a cross-sectional view of a display panel that corresponds to the line I-I′ in FIG. 3 according to one or more embodiments of the present disclosure. FIG. 4B is a cross-sectional view of a display panel that corresponds to the line II-II′ in FIG. 3 according to one or more embodiments of the present disclosure. For example, FIG. 4A is a view illustrating an example of a cross-sectional configuration or arrangement of one pixel PX as illustrated in FIG. 3. The pixel PX may be one of the pixels PX₁₁ to PXₙₘ as illustrated in FIG. 3.

Referring to FIG. 4A, the pixel PX may include a light emitting element OLED and a transistor TR connected to the light emitting element OLED. The light emitting element OLED may include a first electrode AE, a second electrode CE, a hole control layer HCL, an electron control layer ECL, and an emission layer EML. The first electrode AE may be an anode electrode, and the second electrode CE may be a cathode electrode. The light emitting element OLED may be defined as an organic light emitting element.

The display area DA may include an emission area PXA that corresponds to each pixel PX and a non-emission area NPXA around the emission area PXA. The light emitting element OLED may be arranged in the emission area PXA, and the transistor TR may be arranged in the non-emission area NPXA.

The transistor TR and the light emitting element OLED may be arranged on a substrate SUB. A buffer layer BFL may be arranged on the substrate SUB, and the buffer layer BFL may include an inorganic material.

A semiconductor layer SM of the transistor TR may be arranged on the buffer layer BFL. The semiconductor layer SM may include a semiconductor including an inorganic material, such as amorphous (e.g., non-crystalline) silicon and/or polysilicon, or an organic semiconductor. In one or more embodiments, the semiconductor layer SM may include an oxide semiconductor. In FIG. 4A, the semiconductor layer SM may include a source region, a drain region, and a channel region between the source region and the drain region.

An insulating layer INS may be arranged on the buffer layer BFL so as to cover the semiconductor layer SM. The insulating layer INS may include an inorganic material. A gate electrode GE of the transistor TR, which overlaps the semiconductor layer SM, may be arranged on the insulating layer INS. The gate electrode GE may overlap the channel region of the semiconductor layer SM.

A first insulating layer INS1 may be arranged on the insulating layer INS so as to cover the gate electrode GE. The first insulating layer INS1 may include an organic material and/or an inorganic material.

A source electrode SE and a drain electrode DE of the transistor TR may be arranged to be spaced and/or apart (e.g., spaced apart or separated) from each other on the first insulating layer INS1. The source electrode SE may be connected to the source region of the semiconductor layer SM through a first contact hole CH1 defined in the insulating layer INS and the first insulating layer INS1. The drain electrode DE may be connected to the drain region of the semiconductor layer SM through a second contact hole CH2 defined in the insulating layer INS and the first insulating layer INS1.

The source electrode SE may be connected to a second power line PL2 through the connection line CNL as illustrated in FIG. 3. The source electrode SE may be to receive a second voltage through the second power line PL2 and the connection line CNL.

A second insulating layer INS2 may be arranged on the first insulating layer INS1 so as to cover the source electrode SE and the drain electrode DE of the transistor TR. The second insulating layer INS2 may include an organic material. A connection electrode CNE may be arranged on the second insulating layer INS2. The connection electrode CNE may be connected to the drain electrode DE through a third contact hole CH3 defined in the second insulating layer INS2.

A third insulating layer INS3 may be arranged on the second insulating layer INS2 so as to cover the connection electrode CNE. The first electrode AE may be arranged on the third insulating layer INS3. The first electrode AE may be connected to the connection electrode CNE through a fourth contact hole CH4 defined in the third insulating layer INS3.

The first electrode AE may be connected to the second power line PL2 and the connection line CNL as illustrated in FIG. 3, through the connection electrode CNE and the transistor TR. The first electrode AE may be to receive the second voltage through the connection electrode CNE and the transistor TR.

A pixel defining film PDL which exposes a certain (e.g., set or predetermined) portion of the first electrode AE may be arranged on the first electrode AE and the third insulating layer INS3. An opening portion PX_OP to expose the certain portion of the first electrode AE may be defined in the pixel defining film PDL.

The hole control layer HCL may be arranged on the first electrode AE and the pixel defining film PDL. The hole control layer HCL may be arranged, in common, in the emission area PXA and the non-emission area NPXA. The hole control layer HCL may include a hole transport layer, and further include a hole injection layer.

The emission layer EML may be arranged on the hole control layer HCL. The emission layer EML may be arranged in an area that corresponds to the opening portion PX_OP. For example, the emission layer EML may be separated from each other between the pixels PX. The emission layer EML may include an organic material and/or an inorganic material. The emission layer EML may be to generate light of one color of red, green, and blue colors. However, the emission layer EML is not limited thereto and may generate white light by combination of organic materials which generate the red color, the green color, and the blue color.

The electron control layer ECL may be arranged on the emission layer EML. The electron control layer ECL may be arranged on the hole control layer HCL so as to cover the emission layer EML. For example, the electron control layer ECL may be arranged, in common, in the emission area PXA and the non-emission area NPXA. The electron control layer ECL may include an electron transport layer, and further include an electron injection layer.

The second electrode CE may be arranged on the electron control layer ECL. The second electrode CE may be arranged, in common, on the pixels PX. The second electrode CE may be connected to a first power line PL1 as illustrated in FIG. 4B. The second electrode CE may be to receive a first voltage through the first power line PL1.

An encapsulation layer TFL may be arranged on the second electrode CE. The encapsulation layer TFL may include a first encapsulation layer EN1 arranged on the second electrode CE, a second encapsulation layer EN2 arranged on the first encapsulation layer EN1, and a third encapsulation layer EN3 arranged on the second encapsulation layer EN2. The first encapsulation layer EN1 and the third encapsulation layer EN3 may be inorganic insulating (e.g., electrically insulating) layers, and the second encapsulation layer EN2 may be an organic insulating (e.g., electrically insulating) layer. In one or more embodiments, the first encapsulation layer EN1 may be referred to as a first inorganic layer, the second encapsulation layer EN2 may be referred to as an organic layer, and the third encapsulation layer EN3 may be referred to as a second inorganic layer.

The first encapsulation layer EN1 and the third encapsulation layer EN3 may be to protect the pixel PX from moisture and/or oxygen. The second encapsulation layer EN2 may be to protect the pixel PX from foreign matter, such as dust particles. The input sensing module may be arranged on the encapsulation layer TFL.

The layers from the buffer layer BFL to the third insulating layer INS3 may be defined as a circuit element layer DP-CL. The layers from the first electrode AE to the second electrode CE may be defined as a display element layer DP-OLED.

The first voltage may be applied to the second electrode CE. The second voltage may be applied to the first electrode AE of the light emitting element OLED through the transistor TR. A hole and an electron injected into the emission layer EML may be combined with each other to generate an exciton, and the light emitting element OLED may be to emit light while the exciton is transited to a ground state. As the light emitting element OLED emits the light, an image may be displayed.

Referring to FIG. 4B, the first power line PL1 and the second power line PL2 may be arranged on a non-display area NDA of the substrate SUB.

The second power line PL2 may be arranged on the first insulating layer INS1, and the second insulating layer INS2 may be arranged on the second power line PL2. In FIG. 4B, the second power line PL2 may be connected to the transistor TR through the connection line CNL as illustrated in FIG. 3.

The buffer layer BFL, the insulating layer INS, and the first insulating layer INS1 may be arranged on a display area DA and extend to the non-display area NDA. The buffer layer BFL and the insulating layer INS may further extend to the non-display area NDA than the first insulating layer INS1 does.

The second insulating layer INS2 and the third insulating layer INS3 may be arranged on the display area DA and extend to the non-display area NDA. The second insulating layer INS2 and the third insulating layer INS3 may extend to a portion of the non-display area NDA, which is adjacent to a boundary between the display area DA and the non-display area NDA. The first insulating layer INS1 may further extend to the non-display area NDA than the second insulating layer INS2 and the third insulating layer INS3 do.

The pixel defining film PDL may be arranged on the display area DA. The hole control layer HCL and the electron control layer ECL, which are arranged on the display area DA, may extend to the non-display area NDA and be arranged on the third insulating layer INS3.

The display device DD may include a plurality of dams DM1, DM2, and DM3. The plurality of dams DM1, DM2, and DM3 may include a first dam DM1, a second dam DM2, and a third dam DM3. The first dam DM1, the second dam DM2, and the third dam DM3 may be arranged in sequence in an opposite direction to the second direction DR2. The first dam DM1, the second dam DM2, and the third dam DM3 may be arranged on the non-display area NDA. The first dam DM1, the second dam DM2, and the third dam DM3 may be arranged on the first insulating layer INS1 in the non-display area NDA. The first dam DM1, the second dam DM2, and the third dam DM3 may be arranged to be spaced and/or apart (e.g., spaced apart or separated) from edges of the second insulating layer INS2 and the third insulating layer INS3 (e.g., spaced from edges of the second and third insulating layers INS2 and INS3).

The first dam DM1 may include a (1-1)-th sub-dam DM1_1 and a (1-2)-th sub-dam DM1_2 arranged on the (1-1)-th sub-dam DM1_1. The (1-1)-th sub-dam DM1_1 may include substantially the same material as the third insulating layer INS3. The (1-2)-th sub-dam DM1_2 may include substantially the same material as the pixel defining film PDL.

The second dam DM2 may include a (2-1)-th sub-dam DM2_1 and a (2-2)-th sub-dam DM2_2 arranged on the (2-1)-th sub-dam DM2_1. The (2-1)-th sub-dam DM2_1 may include substantially the same material as the (1-1)-th sub-dam DM1_1. The (2-2)-th sub-dam DM2_2 may include substantially the same material as the (1-2)-th sub-dam DM1_2.

The third dam DM3 may include a (3-1)-th sub-dam DM3_1, a (3-2)-th sub-dam DM3_2 arranged on the (3-1)-th sub-dam DM3_1, and a (3-3)-th sub-dam DM3_3 arranged on the (3-2)-th sub-dam DM3_2. The (3-1)-th sub-dam DM3_1 may include substantially the same material as the second insulating layer INS2. The (3-2)-th sub-dam DM3_2 may include substantially the same material as the (1-1)-th sub-dam DM1_1 and the (2-1)-th sub-dam DM2_1. The (3-3)-th sub-dam DM3_3 may include substantially the same material as the (1-2)-th sub-dam DM1_2 and the (2-2)-th sub-dam DM2_2.

However, this is illustrative, and a component included in the first dam DM1, a component included in the second dam DM2, and a component included in the third dam DM3 may include different materials.

The first power line PL1 may be arranged on the insulating layer INS that extends from the first insulating layer INS1 in the non-display area NDA. The first power line PL1 may extend onto the first insulating layer INS1 in the non-display area NDA. The first power line PL1 may extend toward an edge of the second insulating layer INS2.

The first power line PL1 may be arranged below each of the first dam DM1, the second dam DM2, and the third dam DM3, and extend below each of the first dam DM1, the second dam DM2, and the third dam DM3. For example, the first power line PL1 may pass between each of the first dam DM1, the second dam DM2, and the third dam DM3 and the first insulating layer INS1 to extend onto the second insulating layer INS2. The first power line PL1 may be arranged on an edge of the second insulating layer INS2 and a portion of the second insulating layer INS2 adjacent to the edge of the second insulating layer INS2.

The first power line PL1 may be in contact with the second electrode CE to be electrically connected to the second electrode CE at a portion adjacent to the edge of the second insulating layer INS2. For example, the first power line PL1 may be electrically connected to the second electrode CE at the portion adjacent to the edge of the second insulating layer INS2. A portion, at which the first power line PL1 is in contact with the second electrode CE and electrically connected to the second electrode CE, may be defined as a contact portion CNP. As a result, the first power line PL1 may be electrically connected to the pixel PX.

The first encapsulation layer EN1 may extend to the non-display area NDA. In the non-display area NDA, the first encapsulation layer EN1 may be arranged on the second electrode CE, the first power line PL1, the first dam DM1, the second dam DM2, and the third dam DM3.

The second encapsulation layer EN2 may extend to the non-display area NDA. The second encapsulation layer EN2 may be arranged to the first dam DM1. The first encapsulation layer EN1 may further extend to the non-display area NDA than the second encapsulation layer EN2 does.

During manufacture of a display device DD, an organic material having flowability may be cured to provide the second encapsulation layer EN2. Even if (e.g., when) the organic material having flowability flows to the non-display area NDA, the organic material may be blocked by the first dam DM1. In one or more embodiments, the organic material that overflows the first dam DM1 may be additionally blocked by the second dam DM2 and the third dam DM3.

The third encapsulation layer EN3 may extend to the non-display area NDA. In the non-display area NDA, the third encapsulation layer EN3 may be arranged on the first encapsulation layer EN1 and the second encapsulation layer EN2.

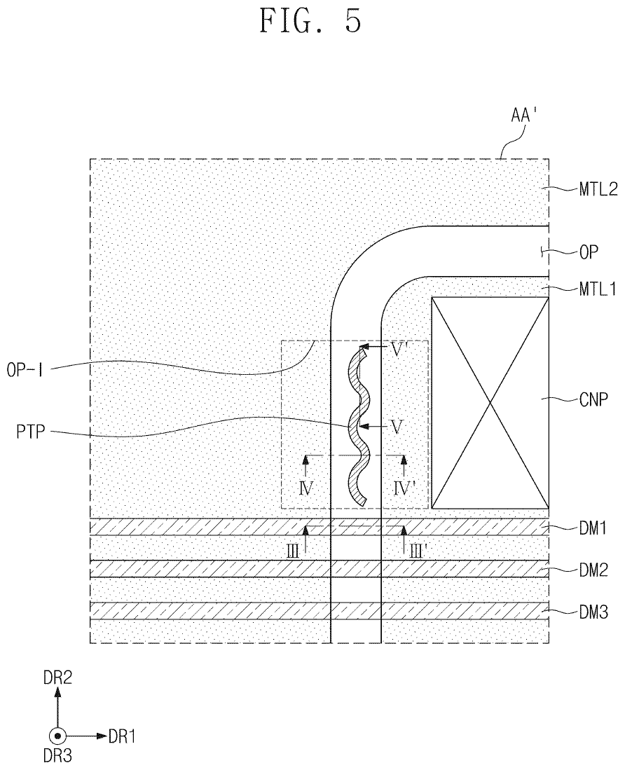

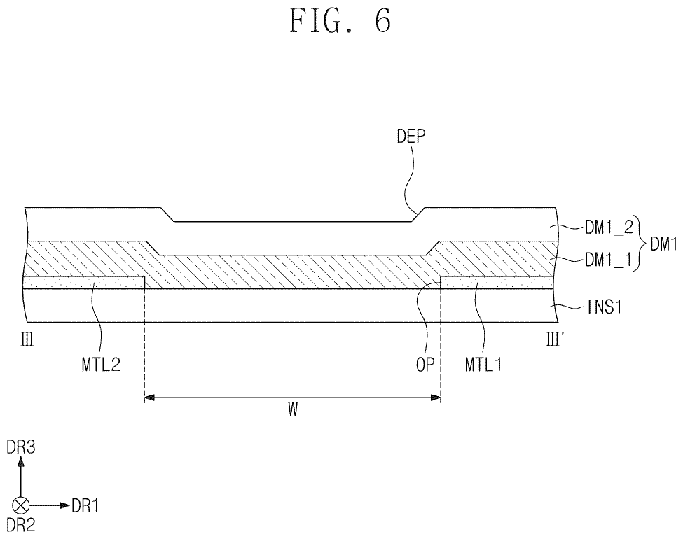

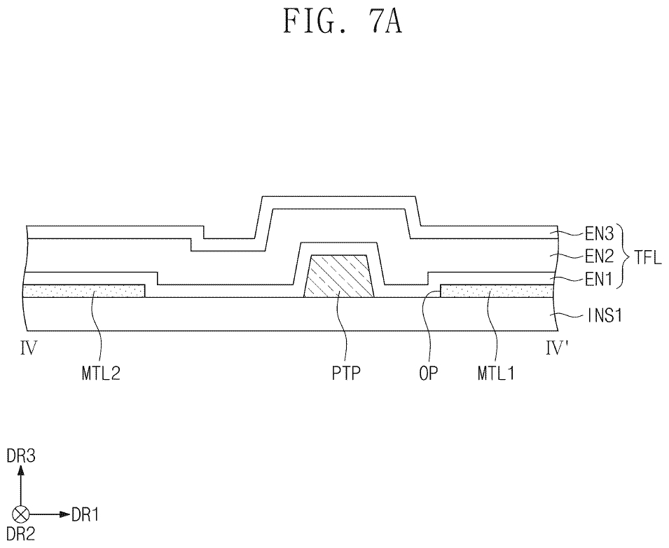

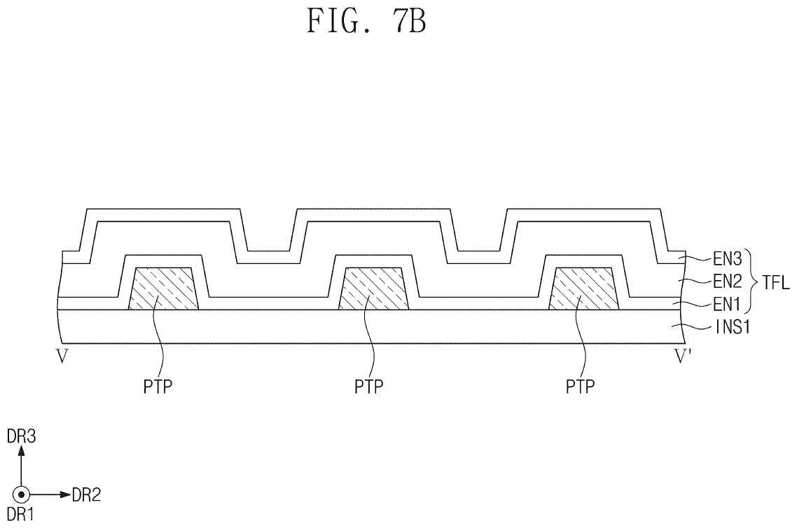

FIG. 5 is an enlarged view of area AA′ as illustrated in FIG. 3. FIG. 6 is a cross-sectional view of a display panel that corresponds to the line III-III′ in FIG. 5 according to one or more embodiments of the present disclosure. FIG. 7A is a cross-sectional view of a display panel that corresponds to the line IV-IV′ in FIG. 5 according to one or more embodiments of the present disclosure. FIG. 7B is a cross-sectional view of a display panel that corresponds to the line V-V′ in FIG. 5 according to one or more embodiments of the present disclosure. Hereinafter, contents duplicated with the contents as described in one or more embodiments will be described with like reference numbers or symbols and briefly.

Referring to FIG. 5, the display panel DP (see FIG. 4B) according to one or more embodiments of the present disclosure may include a metal layer MTL. The metal layer MTL may include a first metal layer MTL1 and a second metal layer MTL2. For example, the circuit layer DP-CL (see FIG. 4B) according to one or more embodiments of the present disclosure may include the first metal layer MTL1 and the second metal layer MTL2. The first metal layer MTL1 may correspond to the first power line PL1 as illustrated in FIG. 3, and the second metal layer MTL2 may correspond to the second power line PL2 as illustrated in FIG. 3. For example, the pixel PX (see FIG. 4B) may be to receive a first voltage through the first metal layer MTL1 and receive a second voltage through the second metal layer MTL2. Each of the first metal layer MTL1 and the second metal layer MTL2 may be arranged at a lower end of the display panel DP (see FIG. 4B) and be provided as one-body metal. However, embodiments of the present disclosure are not limited thereto, and each of the first metal layer MTL1 and the second metal layer MTL2 may be arranged at an upper end of the display panel DP (see FIG. 4B) and be provided as one-body metal.

Referring to FIGS. 5 and 6 together, the first metal layer MTL1 and the second metal layer MTL2 may be spaced and/or apart (e.g., spaced apart or separated) from each other on a plane (e.g., in a plan view). An opening portion OP may be defined between the first metal layer MTL1 and the second metal layer MTL2. The opening portion OP may be a space, in which the first metal layer MTL1 and the second metal layer MTL2 are not provided, and extend in the first direction DR1 and the second direction DR2.

A distance between the first metal layer MTL1 and the second metal layer MTL2 may be defined as a width W of the opening portion OP in the first direction DR1. The width W of the opening portion OP in the first direction DR1 may be about 80 μm to about 120 μm. For example, the width W of the opening portion OP in the first direction DR1 may be about 100 μm. Each of the first metal layer MTL1 and the second metal layer MTL2 may have a thickness of about 3000 Å to about 7000 Å.

According to one or more embodiments of the present disclosure, the first dam DM1 may further include a recessed portion DEP. The recessed portion DEP may be defined in an area that overlaps the opening portion OP in which the first metal layer MTL1 and the second metal layer MTL2 are not provided. A width of the recessed portion DEP may be less than the width W of the opening portion OP in the first direction DR1. However, the width of the recessed portion DEP may be substantially the same as the width W of the opening portion OP in the first direction DR1. For example, the width of the recessed portion DEP may be about 80 μm to about 120 μm. In one or more embodiments, a thickness of the recessed portion DEP may be substantially the same as the thickness of each of the first metal layer MTL1 and the second metal layer MTL2. For example, the thickness of the recessed portion DEP may be about 3000 Å to about 7000 Å.

Referring to FIGS. 4B and 5 together, a circuit layer DP-CL according to one or more embodiments of the present disclosure may include a pattern portion PTP. For example, a third insulating layer INS3 according to one or more embodiments of the present disclosure may include the pattern portion PTP. The pattern portion PTP may overlap the opening portion OP. An open portion OP-I which exposes a portion of the first metal layer MTL1 and the second metal layer MTL2 may be defined in the third insulating layer INS3. The open portion OP-I may be a portion which is etched and removed from the third insulating layer INS3. The pattern portion PTP may be arranged in the open portion OP-I. A contact portion CNP may be arranged at a position adjacent to the open portion OP-I. The contact portion CNP may be a portion at which the first metal layer MTL1 is electrically connected to the second electrode CE (see FIG. 4B).

According to one or more embodiments of the present disclosure, the pattern portion PTP may include a wavy shape (e.g., a substantially wavy shape) on a plane (e.g., in a plan view). The pattern portion PTP may have a surface concave in the first direction DR1 or in an opposite direction to the first direction DR1. The pattern portion PTP may be arranged adjacent to the first dam DM1. For example, the pattern portion PTP may be arranged adjacent to the first dam DM1 in the second direction DR2.

Referring to FIGS. 4B to 7B together, the pattern portion PTP may include substantially the same material as the first dam DM1. For example, the pattern portion PTP may include substantially the same material as a (1-1)-th sub-dam DM1_1. If (e.g., when) forming a second encapsulation layer EN2, a process of curing an organic material having flowability may be included, and thus the organic material having flowability may flow into the non-display area NDA through the recessed portion DEP arranged in the first dam DM1. However, the pattern portion PTP arranged adjacent to the recessed portion DEP of the first dam DM1 may block the organic material having flowability such that the organic material does not flow into the recessed portion DEP, thereby providing the display device DD (see FIG. 2A) having reliability.

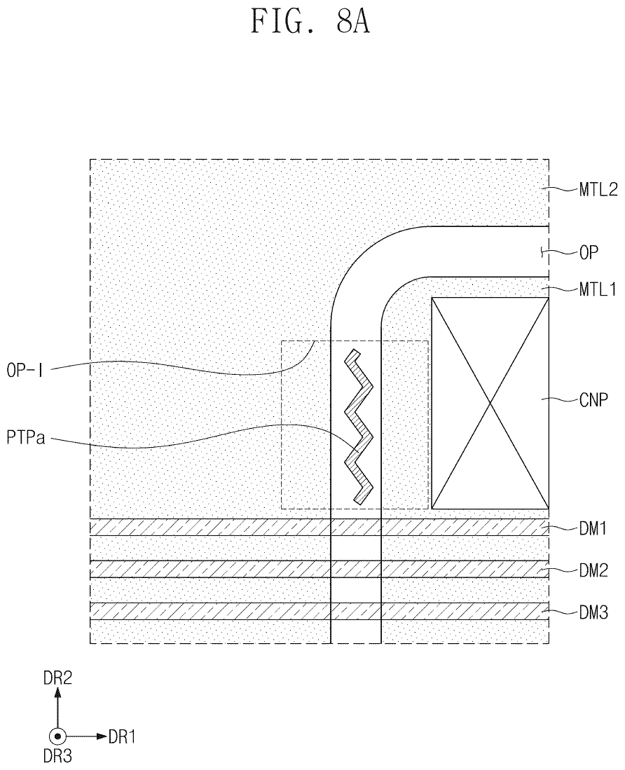

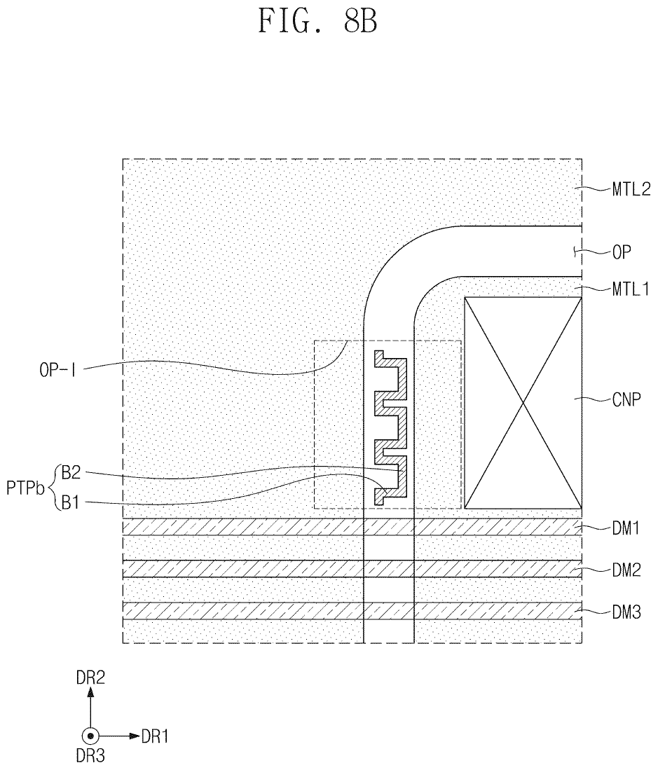

FIGS. 8A and 8B are each an enlarged view of a portion of a display panel according to one or more embodiments of the present disclosure. For example, FIGS. 8A and 8B are each an enlarged view of area AA′ as illustrated in FIG. 3. Hereinafter, contents duplicated with the contents as described in one or more embodiments will be described with like reference numbers or symbols and briefly.

Referring to FIG. 8A, a pattern portion PTPa according to one or more embodiments of the present disclosure may include a zigzag shape (e.g., a substantially zigzag shape). For example, the pattern portion PTPa may include the zigzag shape which is arranged in an open portion OP-I and extends in the second direction DR2.

Referring to FIG. 8B, a pattern portion PTPb according to one or more embodiments of the present disclosure may include a first portion B1 that extends in the first direction DR1 and a second portion B2 that extends in the second direction DR2. The first portion B1 and the second portion B2 may be provided as one body. Each of the first portion B1 and the second portion B2 may be provided in plurality. The plurality of first portions B1 and the plurality of second portions B2 may be arranged in sequence in the second direction DR2.

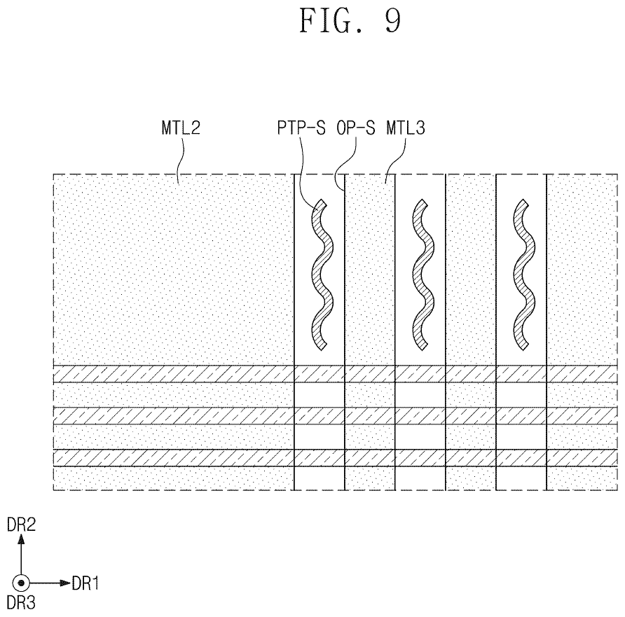

FIG. 9 is an enlarged view of area BB′ as illustrated in FIG. 3.

Referring to FIG. 9, a metal layer MTL according to one or more embodiments of the present disclosure may further include a third metal layer MTL3. The third metal layer MTL may correspond to the data lines DL1 to DLm as illustrated in FIG. 3. In one or more embodiments, the third metal layer MTL3 may be a portion electrically connected to the data lines DL1 to DLm as illustrated in FIG. 3. The third metal layer MTL3 may be spaced and/or apart (e.g., spaced apart or separated) from a second metal layer MTL2 in the first direction DR1. For example, the pixel PX (see FIG. 4B) may be to receive data voltages through the third metal layer MTL3. The third metal layer MTL3 may be arranged at a lower end of the display panel DP (see FIG. 4B) and be provided as one-body metal.

A sub-opening portion OP-S may be defined between the second metal layer MTL2 and the third metal layer MTL3. The sub-opening portion OP-S may be a space, in which the second metal layer MTL2 and the third metal layer MTL3 are not provided, and extend in the second direction DR2. The third metal layer MTL3 may be provided in plurality. A space between the plurality of third metal layers MTL3 may be also defined as the sub-opening portion OP-S. For example, the sub-opening portion OP-S may be provided in plurality.

The circuit layer DP-CL (see FIG. 4B) according to one or more embodiments of the present disclosure may include an auxiliary pattern portion PTP-S. For example, the third insulating layer INS3 (see FIG. 4B) according to one or more embodiments of the present disclosure may include the auxiliary pattern portion PTP-S. The auxiliary pattern portion PTP-S may overlap the sub-opening portion OP-S.

The auxiliary pattern portion PTP-S may include substantially the same shape as the pattern portion PTP as illustrated in FIG. 5. However, embodiments of the present disclosure are not limited thereto, and the shape of the auxiliary pattern portion PTP-S may be different from the shape of the pattern portion PTP. The auxiliary pattern portion PTP-S may be provided in plurality to correspond to the plurality of sub-opening portions OP-S. The shapes of the plurality of auxiliary pattern portions PTP-S may be substantially the same.

The first metal layer and the second metal layer that are spaced and/or apart (e.g., spaced apart or separated) from each other may be provided at the lower end of the display panel according to one or more embodiments of the present disclosure. If (e.g., when) forming the encapsulation layer on the display layer, the organic material having the flowability may flow to the non-display area through the opening portion between the first metal layer and the second metal layer. The display device according to one or more embodiments of the present disclosure may include the pattern portion, provided adjacent to the dam which blocks the organic material, to block the organic material such that the organic material does not flow into the non-display area, thereby providing the display device having the reliability.

A display device, an electronic device, an electronic apparatus, a device for manufacturing substantially the same and/or any other relevant devices or components according to one or more embodiments of the present disclosure may be implemented by utilizing any suitable hardware, firmware (e.g., an application-specific integrated circuit), software, or a (e.g., any suitable) combination of software, firmware, and hardware. For example, the one or more components of the device may be provided on one integrated circuit (IC) chip or on separate IC chips. Further, the one or more components of the device may be implemented on a flexible printed circuit film, a tape carrier package (TCP), and/or a printed circuit board (PCB) or provided on one substrate. Further, the one or more components of the device may be a process or thread, running on one or more processors, in one or more computing devices, executing computer program instructions and interacting with other system components for performing the one or more functionalities described herein. The computer program instructions may be stored in a memory which may be implemented in a computing device using a standard memory device, such as, for example, a random access memory (RAM). The computer program instructions may also be stored in other non-transitory computer readable media, such as, for example, a CD-ROM, flash drive, and/or the like. Also, a person of skill in the art should recognize that the functionality of one or more computing devices may be combined or integrated into a single computing device, or the functionality of a particular computing device may be distributed across one or more other computing devices without departing from the scope of the present disclosure.

Although one or more embodiments of the present disclosure have been described with reference to the accompanying drawings, those of ordinary skill in the art to which the present disclosure pertains will understand that the subject matter of the present disclosure may be embodied in different forms and should not be construed as being limited to one or more embodiments set forth herein. It therefore will be understood that one or more embodiments described herein are just illustrative but not limitative in all aspects.

It should be understood that embodiments described herein should be considered in a descriptive sense only and not for purposes of limitation. Descriptions of features or aspects within each embodiment should typically be considered as available for other similar features or aspects in one or more embodiments. While one or more embodiments have been described with reference to the drawings, it will be understood by those of ordinary skill in the art that one or more suitable changes in form and details may be made therein without departing from the spirit and scope as defined by the following claims and equivalents thereof.

What is claimed is:

1. A display device, comprising:
a base layer divided into a display area and a non-display area around the display area;
a circuit layer arranged on the base layer and comprising at least one metal layer and an insulating layer on the at least one metal layer; and
a display element layer arranged on the circuit layer and comprising a light emitting element electrically connected to the at least one metal layer,
wherein the at least one metal layer comprises a first metal layer and a second metal layer which are arranged in the non-display area and spaced from each other in a first direction, and
wherein the insulating layer comprises a pattern portion that is defined between the first metal layer and the second metal layer and that overlaps an opening portion that extends in a second direction that crosses the first direction.

2. The display device as claimed in claim 1, further comprising a dam that is arranged in the non-display area and that extends in the first direction,
wherein the pattern portion is adjacent to the dam.

3. The display device as claimed in claim 2, wherein the dam comprises a recessed portion defined in an area that overlaps the opening portion.

4. The display device as claimed in claim 2, wherein the dam comprises substantially the same material as the pattern portion.

5. The display device as claimed in claim 2, wherein the dam comprises a plurality of dams, and the plurality of dams are spaced from each other in the second direction.

6. The display device as claimed in claim 1, further comprising an encapsulation layer arranged on the display element layer and comprising a first inorganic layer, an organic layer on the first inorganic layer, and a second inorganic layer on the organic layer.

7. The display device as claimed in claim 6, further comprising a dam that is arranged in the non-display area and that extends in the first direction,
wherein the organic layer is in contact with the dam.

8. The display device as claimed in claim 1, wherein the insulating layer comprises an open portion which exposes at least a portion of the first metal layer and the second metal layer, and
wherein the pattern portion is in the open portion.

9. The display device as claimed in claim 1, wherein the pattern portion comprises a surface concave in the first direction or in an opposite direction to the first direction.

10. The display device as claimed in claim 1, wherein the pattern portion comprises a zigzag shape.

11. The display device as claimed in claim 1, wherein the pattern portion comprises:
a first portion that extends in the first direction; and
a second portion that extends in the second direction.

12. The display device as claimed in claim 1, wherein the first metal layer is to receive a first voltage, and the second metal layer is to receive a second voltage having a higher level than the first voltage.

13. The display device as claimed in claim 11, wherein the first metal layer is electrically connected to a cathode of the light emitting element through a contact hole defined in the insulating layer.

14. The display device as claimed in claim 1, wherein a distance by which the first metal layer and the second metal layer are spaced from each other is about 80 μm to about 120 μm.

15. The display device as claimed in claim 1, wherein the at least one metal layer further comprises a third metal layer spaced from the second metal layer in the first direction, and
wherein a sub-opening portion is defined between the second metal layer and the third metal layer.

16. The display device as claimed in claim 15, wherein the insulating layer further comprises an auxiliary pattern portion that overlaps the sub-opening portion.

17. The display device as claimed in claim 16, wherein the auxiliary pattern portion comprises substantially the same shape as the pattern portion.

18. The display device as claimed in claim 16, wherein the auxiliary pattern portion comprises a plurality of auxiliary pattern portions, and the plurality of auxiliary pattern portions are substantially the same in shape.

19. The display device as claimed in claim 15, wherein the third metal layer is to receive a data voltage.

20. An electronic device, comprising:
a housing:
an electronic module inside the housing; and
a display device that overlaps the electronic module,
wherein the display device comprises:
a base layer divided into a display area and a non-display area around the display area;
a circuit layer arranged on the base layer and comprising at least one metal layer and an insulating layer on the at least one metal layer; and
a display element layer arranged on the circuit layer and comprising a light emitting element electrically connected to the at least one metal layer,
wherein the at least one metal layer comprises a first metal layer and a second metal layer which are arranged in the non-display area and spaced from each other in a first direction, and
wherein the insulating layer comprises a pattern portion that is defined between the first metal layer and the second metal layer and that overlaps an opening portion that extends in a second direction that crosses the first direction.
